(19) United States
(12) Patent Application Publication
(10) Pub. No.: US 2015/0098288 A1
(43) Pub. Date: Apr. 9, 2015

(54) ELECTRONIC DEVICE INCLUDING SEMICONDUCTOR MEMORY AND OPERATION METHOD OF THE SAME

(71) Applicant: SK hynix Inc., Gyeonggi-do (KR)

(72) Inventors: Ji-Hyae BAE, Gyeonggi-do (KR); Yong-Ho KIM, Gyeonggi-do (KR)

(73) Assignee: SK hynix Inc., Gyeonggi-do (KR)

(21) Appl. No.: 14/256,711

(22) Filed: Apr. 18, 2014

(30) Foreign Application Priority Data
Oct. 7, 2013 (KR) 10-2013-0119040

(51) Int. Cl. G11C 11/406; G11C 11/408

(52) U.S. Cl. CPC G11C 11/40618; G11C 11/408
USPC 365/222; 365/230.03; 365/230.01

(57) ABSTRACT

An electronic device includes a semiconductor memory. The semiconductor memory includes a cell array including first to N^{th} word lines, where the N is an integer equal to or larger than 2, first to N^{th} memory sets respectively corresponding to the first to N^{th} word lines, and an activation number updating block configured to, when a K^{th} word line of the word lines is activated, initialize a value stored in a K^{th} memory set and increase values stored in memory sets corresponding to adjacent word lines of the K^{th} word line, among the memory sets, wherein the K is an integer equal to or larger than 1 and equal to or smaller than N.

### CROSS-REFERENCE TO RELATED APPLICATIONS

The present application claims priority of Korean Patent Application No. 10-2013-0119040, entitled “ELECTRONIC DEVICE INCLUDING SEMICONDUCTOR MEMORY AND OPERATION METHOD OF THE SAME” and filed on Oct. 7, 2013, which is incorporated herein by reference in its entirety.

### TECHNICAL FIELD

Various embodiments of the present invention relate to memory circuits or devices, and more particularly, to their applications in electronic devices or systems.

### BACKGROUND

As the degree of integration of a memory increases, an interval between the plurality of word lines included in the memory is reduced. As the interval between the word lines is reduced, a coupling effect between adjacent word lines increases.

Whenever data is inputted and outputted to and from a memory cell, a word line shifts between an activated (active) state and a deactivated (inactive) state. In this regard, as the coupling effect between adjacent word lines increases as described above, a word line frequently activated may damage the data of a memory cell coupled with another word line adjacent thereto. Such a phenomenon is called word line disturbance. Due to the word line disturbance, the data of a memory cell may be damaged before the memory cell is refreshed.

FIG. 1 is a diagram explaining word line disturbance and illustrating a part of a cell array included in a memory.

In FIG. 1, ‘WLL’ corresponds to a word line having a large number of activation times, and ‘WLL−1’ and ‘WLL+1’ correspond to word lines, which are disposed adjacent to the word line ‘WLL’, that is, word lines, which are adjacent to a word line having a large number of activation times (i.e. large number of activations). Furthermore, ‘CL’ indicates a memory cell coupled with the word line ‘WLL’, ‘CL−1’ indicates a memory cell coupled with the word line ‘WLL−1’, and ‘CL+1’ indicates a memory cell coupled with the word line ‘WLL+1’. The respective memory cells ‘CL’, ‘CL−1’ and ‘CL+1’ include cell transistors TL, TL−1 and TL+1 and cell capacitors CAPL, CAPL−1 and CAPL+1.

In FIG. 1, when the word line ‘WLL’ is activated or deactivated, the voltages of the word lines ‘WLL−1’ and ‘WLL+1’ are increased or decreased due to a coupling phenomenon occurring between the word line ‘WLL’ and the word line ‘WLL−1’ or ‘WLL+1’, and an influence is exerted on the amounts of charges of the cell capacitors CAPL−1 and CAPL+1. Therefore, in the case where the activation of the word line ‘WLL’ frequently occurs and the word line ‘WLL’ shifts between an activated state and a deactivated state, changes in the amounts of charges stored in the cell capacitors CAPL−1 and CAPL+1 included in the memory cells ‘CL−1’ and the ‘CL+1’ increase, so that the data of the memory cells ‘CL−1’ and the ‘CL+1’ may be degraded.

Furthermore, as electromagnetic waves, which are generated while the word line shifts between the activated state and the deactivated state, induce or discharge electrons into or from the cell capacitors of the memory cells coupled with adjacent word lines, data of the memory cells are likely to be damaged.

### SUMMARY

Exemplary embodiments of the present invention are directed to memory circuits or devices and their applications in electronic devices or systems, which are capable of preventing the data of word lines from being lost due to frequent activation of adjacent word lines.

In an exemplary embodiment of the present invention, an electronic device is provided to include a semiconductor memory that includes a cell array including first to N^{th} word lines, where the N is an integer equal to or larger than 2, first to N^{th} memory sets respectively corresponding to the first to N^{th} word lines; and an activation number updating block suitable for, when a K^{th} word line of the word lines is activated, initializing a value stored in a K^{th} memory set and increasing values stored in memory sets corresponding to adjacent word lines of the K^{th} word line, among the memory sets, wherein the K is an integer equal to or larger than 1 and equal to or smaller than N. The semiconductor memory may further comprise a weak address storage block suitable for storing an address of a word line corresponding to a memory set of which a value reaches a threshold, among the memory sets.

A word line corresponding to an address stored in the weak address storage block may be refreshed with priority, among the word lines, in a refresh operation of the semiconductor memory.

The semiconductor memory may further include an address mapping block suitable for generating addresses which designate the K^{th} memory set and the memory sets corresponding to the adjacent word lines of the K^{th} word line, in response to an address which designates the K^{th} word line.

The activation number updating block may include an initialization unit suitable for initializing the value stored in the K^{th} memory set when the K^{th} word line is activated, and an increasing unit suitable for increasing by 1 the values stored in the memory sets corresponding to the adjacent word lines of the K^{th} word line when the K^{th} word line is activated.

The semiconductor memory may further include a threshold determination block suitable for determining whether or not the values stored in the memory sets corresponding to the adjacent word lines of the K^{th} word line reach the threshold.

The electronic device may further include a processing system which includes a processor suitable for decoding a command inputted from an outside of the electronic device and control an operation for information based on a result of decoding the command, an auxiliary memory device suitable for storing a program for decoding the command and the information, a main memory device suitable for calling and storing the program and the information from the auxiliary memory device for the processor to perform the operation using the program and the information when executing the program, and an interface device suitable for performing communication between the processor, the auxiliary memory device or the main memory device and the outside, wherein the semiconductor memory unit includes a resistance variable element as a part of the main memory device in the processing system.

The electronic device may further include a data storage system, which includes a storage device suitable for storing data and conserving stored data regardless of power supply, a controller suitable for controlling input and output of data to and from the storage device in response to a command inputted form an outside of the electronic device, a temporary storage device suitable for temporarily storing data exchanged between the storage device and the outside, and an interface suitable for performing communication between at least one of the storage device, the controller and the temporary storage device and the outside, wherein the semiconductor memory unit includes a resistance variable element as a part of the temporary storage device in the data storage system.

The electronic device may further include a memory system, which includes a memory suitable for storing data and conserving stored data regardless of power supply, a memory controller suitable for controlling input and output of data to and from the memory in response to a command inputted form an outside of the electronic device, a buffer memory suitable for buffering data exchanged between the memory and the outside, and an interface suitable for performing communication between at least one of the memory, the memory controller and the buffer memory and the outside, wherein the semiconductor memory unit includes a resistance variable element as a part of the buffer memory in the memory system.

In another exemplary embodiment of the present invention, a method is provided for operating a semiconductor memory, including activating a K^{th} word line of N^{th} word lines in a normal cell array, wherein the N is an integer equal to or larger than 2, and the K is an integer equal to or larger than 1 and equal to or smaller than N, initializing a value stored in a K^{th} memory set corresponding to the K^{th} word line in a dummy cell array, and increasing values stored in memory sets corresponding to adjacent word lines of the K^{th} word line in the dummy cell array.

The method may further include determining whether or not the values stored in the memory sets corresponding to the adjacent word lines reach a threshold, and storing an address of each of the adjacent word lines as a weak address when the value stored in the memory set corresponding to the adjacent word line is determined to reach the threshold.

The method may further include refreshing a word line corresponding to the weak address with priority in a refresh operation of the semiconductor memory.

### BRIEF DESCRIPTION OF THE DRAWINGS

FIG. 1 is a diagram explaining word line disturbance and illustrating a part of a cell array included in a memory.

FIG. 2 is an exemplary configuration diagram of a semiconductor memory device (circuit) in accordance with an embodiment of the present invention.

FIG. 3 is a detailed exemplary configuration diagram of the semiconductor memory device (circuit) in accordance with the embodiment of the present invention.

FIG. 4 is a flow chart explaining operations of the memory device shown in FIGS. 2 and 3.

FIG. 5 shows an example of a configuration diagram of a system implementing memory circuitry in accordance with an embodiment of the present invention.

FIG. 6 shows an example of a configuration diagram of a data storage system implementing memory circuitry in accordance with an embodiment of the present invention.

FIG. 7 shows an example of a configuration diagram of a memory system in accordance with an embodiment of the present invention.

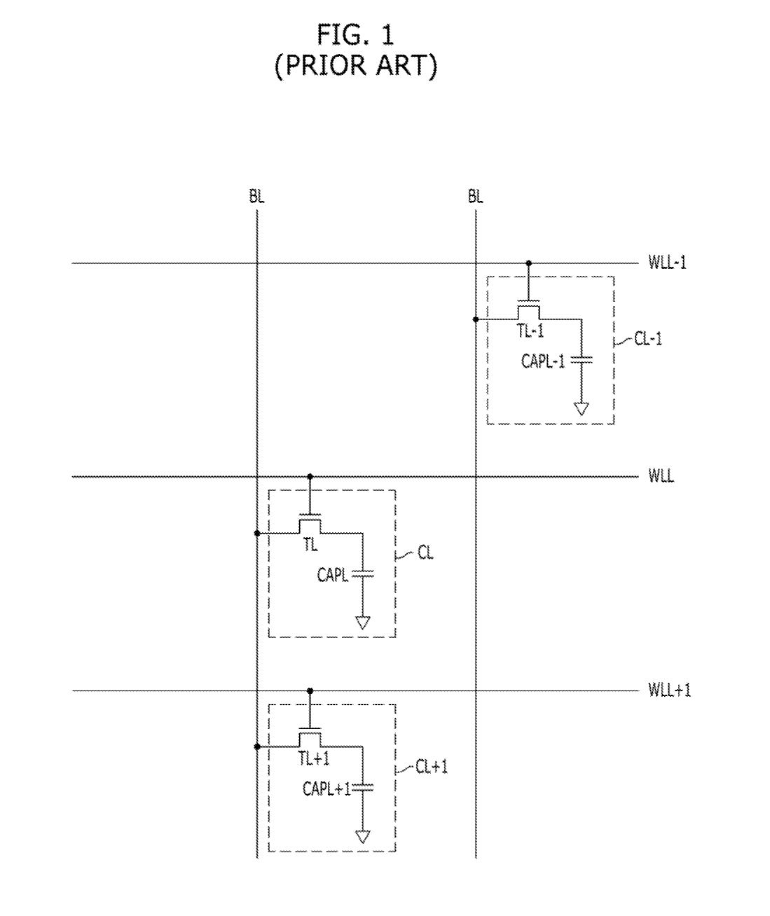

### DETAILED DESCRIPTION

Various examples and implementations of the disclosed technology are described below in detail with reference to the accompanying drawings.

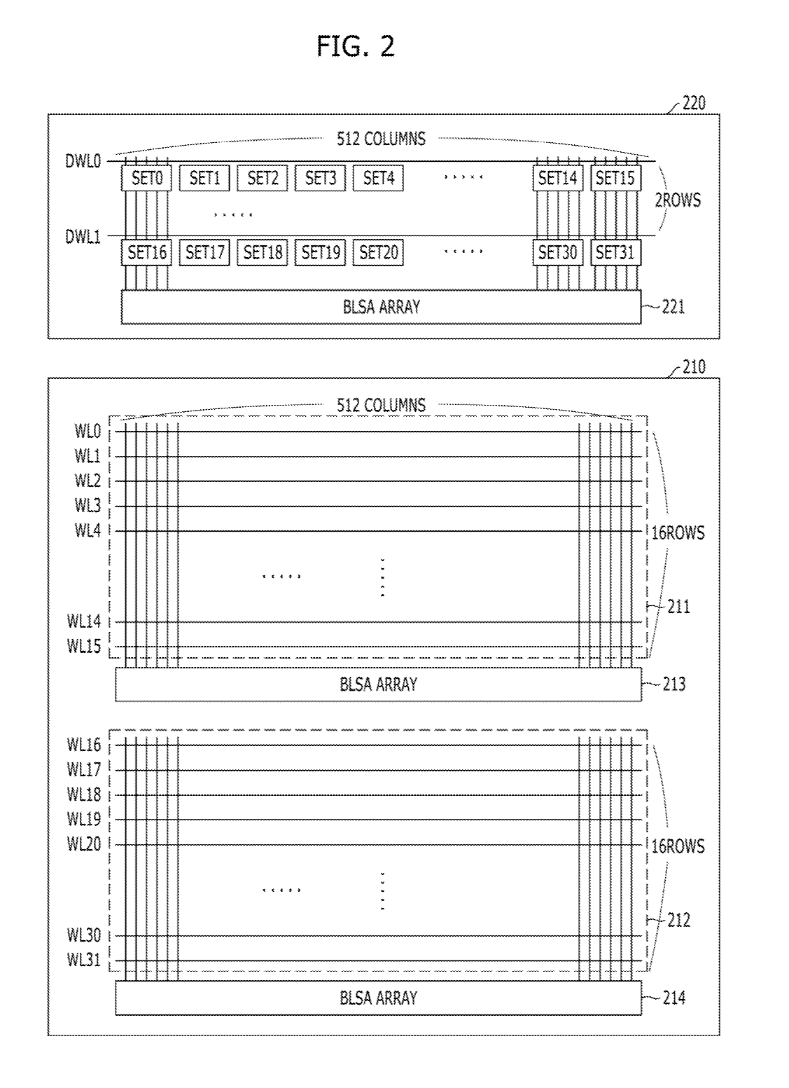

FIG. 2 is an exemplary configuration diagram of a semiconductor memory device (circuit) in accordance with an embodiment of the present invention. In FIG. 2, in order to explain a principle of detecting a word line in a memory device, of which data is highly susceptible to be damaged, the simplified configuration of the memory device is shown.

Referring to FIG. 2, the memory device may include a normal cell array 210 and a dummy cell array 220. The normal cell array 210 may be a cell array for storing the data inputted from an outside of the memory device, and the dummy cell array 220 may be a cell array for recording word lines in the normal cell array, of which data are highly susceptible to be damaged.

The normal cell array 210 may include 32 word lines WL0 to WL31. Among the word lines WL0 to WL31, the word lines WL0 to WL15 and the word lines WL16 to WL31 may be formed to be separated from each other. That is to say, the word lines WL0 to WL15 and the word lines WL16 to WL31 may be included in different cell matrixes 211 and 212. In the normal cell array 210, the number of columns (bit lines) may be 512. In other words, 512 memory cells may correspond to one word line. Therefore, 32 rows×512 columns=16384 memory cells may be included in the normal cell array 210. Although the number of word lines and the number of columns in one normal cell array have been exemplified as 32 and 512, respectively, for simple explanation, it is to be noted as a matter of course that the number of word lines and the number of columns in an actual normal cell array may be several thousands to several ten thousands. Bit line sense amplifier arrays 213 and 214 for sensing and amplifying the data stored in the normal cell array 210 may be disposed on the sides of the cell matrixes 211 and 212.

The dummy cell array 220 may include 2 dummy word lines DWL0 and DWL1 and 512 columns. The memory cells of the dummy cell array 220 may form each memory set SET in a group of 32. Since 2 rows×512 columns=1024 memory cells are included in the dummy cell array 220, the number of memory sets SET0 to SET31 in the dummy cell array 220 may be 1024/32=32. The memory sets SET0 to SET31 in the dummy cell array 220 respectively correspond to the word lines WL0 to WL31. Thus, the number of rows, the number of columns and the number of memory sets SET in the dummy cell array 220 may be changed depending on the number of word lines WL in the normal cell array 210. A bit line sense amplifier array 221 for sensing and amplifying the data stored in the dummy cell array 220 may be disposed.

The memory sets SET0 to SET31 store the numbers of activation times (i.e. number of activations) of adjacent word lines of the respective word lines WL0 to WL31 corresponding to them. If the word lines WL0 to WL31 corresponding to the respective memory sets SET0 to SET31 are activated, the values stored in them are initialized. For example, if the word line WL3 is activated, the values stored in the memory set SET2 and the memory set SET4 corresponding to the adjacent word lines WL2 and WL4 are increased by 1, and the value stored in the memory set SET3 is initialized to 0. If the word line WL15 is activated, the value stored in the memory set SET14 corresponding to the adjacent word line WL14 is increased by 1, and the value stored in the memory set SET15 is initialized to 0. For reference, since the word line WL16 and the word line WL15 are formed separately from each other and do not influence each other, the word line WL16 is not the adjacent word line of the word line WL15.

When a specific word line is activated, the value stored in a memory set corresponding to the adjacent word line of the activated word line is increased by 1, because the probability of the data of the adjacent word line to be lost is increased due to an influence by the activated word line. Further, when a specific word line is activated, the value stored in a memory set corresponding to the activated word line is initialized to 0, because the data of the activated word line is refreshed simultaneously with the activation of the word line, and thus the stability of data is improved.

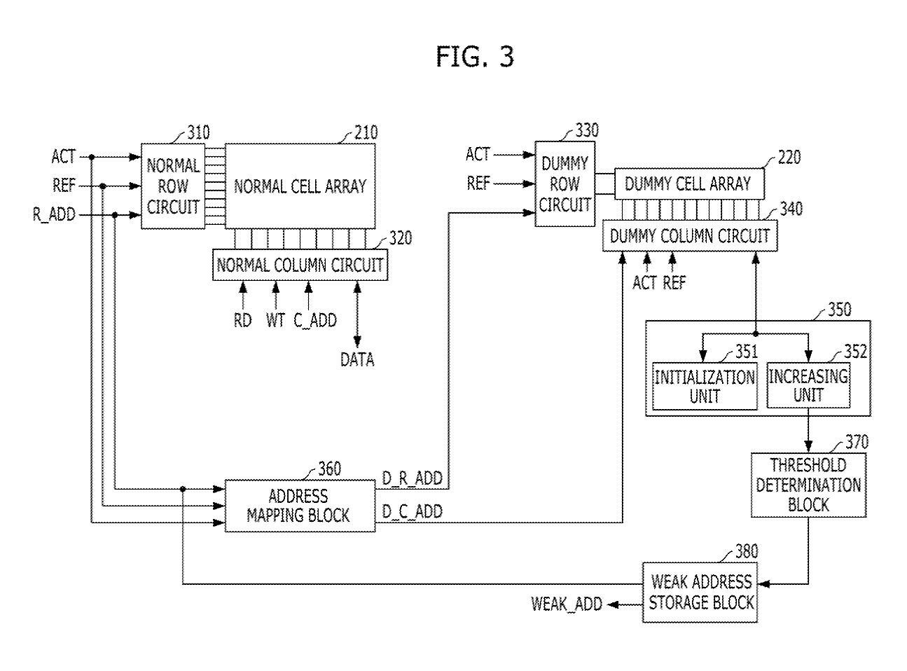

FIG. 3 is a detailed exemplary configuration diagram of the semiconductor memory device (circuit) in accordance with the embodiment of the present invention.

Referring to FIG. 3, the memory device may include, in addition to the normal cell array 210 and the dummy cell array 220, a normal row circuit 310, a normal column circuit 320, a dummy row circuit 330, a dummy column circuit 340, an activation number updating block 350, an address mapping block 360, a threshold determination block 370, and a weak address storage block 380.

The normal row circuit 310 may activate the word line designated by a row address R_ADD among the word lines WL0 to WL31 of the normal cell array 210 in an active operation or a refresh operation. An active signal ACT may be a signal, which is activated in the active operation, and a refresh signal REF may be a signal, which is activated in the refresh operation. The row address R_ADD may be inputted from an outside of the memory device in the active operation, and may be generated in the memory device in the refresh operation.

The normal column circuit 320 may access the column selected by a column address C_ADD in the normal cell array 210 in read and write operations. Data DATA may be read from the memory cells of the selected column in the read operation, and data DATA may be written in the selected column in the write operation. A read signal RD may be a signal, which is activated in the read operation, and a write signal WT may be a signal, which is activated in the write operation.

The address mapping block 360 may generate dummy addresses D_R_ADD and D_C_ADD in response to the row address R_ADD in the active and refresh operations. The dummy addresses D_R_ADD and D_C_ADD may be constituted by a row dummy address D_R_ADD and a column dummy address D_C_ADD. The dummy addresses D_R_ADD and D_C_ADD may be generated such that a memory set corresponding to the word line activated by the row address R_ADD and memory sets corresponding to word lines adjacent to the activated word line may be selected. Since one word line among the 32 word lines WL0 to WL31 is selected by the row address R_ADD and a combination of memory sets selected by the dummy addresses D_R_ADD and D_C_ADD is one combination of 32 combinations, the row address R_ADD and the dummy addresses D_R_ADD and D_C_ADD may be mapped. Table 1 shows relationships between a word line selected by the row address R_ADD and memory sets selected by the dummy addresses D_R_ADD and D_C_ADD corresponding to the row address R_ADD.

TABLE 1

| Word line | Memory sets selected |
|---|---|
| selected by | by D_R_ADD and |
| R_ADD | D_C_ADD |
| WL0 | SET0, SET1 |
| WL1 | SET0, SET1, SET2 |
| WL2 | SET1, SET2, SET3 |
| WL3 | SET2, SET3, SET4 |
| WL4 | SET3, SET4, SET5 |
| WL5 | SET4, SET5, SET6 |
| WL6 | SET5, SET6, SET7 |
| WL7 | SET6, SET7, SET8 |
| WL8 | SET7, SET8, SET9 |
| WL9 | SET8, SET9, SET10 |
| WL10 | SET9, SET10, SET11 |
| WL11 | SET10, SET11, SET12 |
| WL12 | SET11, SET12, SET13 |
| WL13 | SET12, SET13, SET14 |
| WL14 | SET13, SET14, SET15 |
| WL15 | SET14, SET15 |
| WL16 | SET16, SET17 |
| WL17 | SET16, SET17, SET18 |
| WL18 | SET17, SET18, SET19 |
| WL19 | SET18, SET19, SET20 |
| WL20 | SET19, SET20, SET21 |
| WL21 | SET20, SET21, SET22 |
| WL22 | SET21, SET22, SET23 |
| WL23 | SET22, SET23, SET24 |
| WL24 | SET23, SET24, SET25 |
| WL25 | SET24, SET25, SET26 |
| WL26 | SET25, SET26, SET27 |
| WL27 | SET26, SET27, SET28 |
| WL28 | SET27, SET28, SET29 |
| WL29 | SET28, SET29, SET30 |
| WL30 | SET29, SET30, SET31 |
| WL31 | SET30, SET31 |

The dummy row circuit 330 may activate the word line designated by the dummy row address D_R_ADD between the dummy word lines DWL0 and DWL1 of the dummy cell array 220 in the active operation and the refresh operation. The dummy column circuit 340 may access the column selected by the dummy column address D_C_ADD in the dummy cell array 220 in the active operation and the refresh operation. In the active operation and the refresh operation, the memory sets may be selected by the dummy row circuit 330 and the dummy column circuit 340 as shown in Table 1. The dummy column circuit 340 may transfer the values read from selected memory sets to the activation number updating block 350 and write the values updated by the activation number updating block 350 to selected memory sets.

The activation number updating block 350 may initialize the value of a memory set corresponding to a word line activated in the normal cell array 210 to 0 and increase by 1 the values of memory sets corresponding to the adjacent word lines of the word line activated in the normal cell array 210 and transfer the initialized value and the increased values to the dummy column circuit 340. The activation number updating block 350 may include an initialization unit 351 configured to initialize the value of a memory set corresponding to an activated word line, and an increasing unit 352 configured to increase by 1 the values of memory sets corresponding to adjacent word lines.

The threshold determination block 370 may determine whether or not the values of the memory sets, which are increased by the activation number updating block 350, are equal to or larger than a threshold (for example, 60000). If it is determined by the threshold determination block 370 that the value stored in a memory set is equal to or larger than the threshold, the address of a word line corresponding to the memory set is stored as a weak address WEAK_ADD in the weak address storage block 380. For example, when the value stored in the memory set SET7 is equal to or larger than the threshold, the row address R_ADD designating the word line WL7 is stored as the weak address WEAK_ADD in the weak address storage block 380. The weak address storage block 380 may store the weak address WEAK_ADD by adding+1 or −1 to the inputted row address R_ADD. For example, when a row address R_ADD designating a word line WL4 is inputted and the word line WL4 is activated, the values of the memory sets SET3 and SET5 increase. When it is determined that the increasing value of the memory set SET5 is equal to or larger than the threshold, the value of the inputted row address R_ADD+1 may be stored as the weak address WEAK_ADD, and in the case where it is determined that the increasing value of the memory set SET3 is equal to or larger than the threshold, the value of the inputted row address R_ADD−1 may be stored as the weak address WEAK_ADD.

A word line corresponding to the weak address WEAK_ADD stored in the weak address storage block 380 is first refreshed with priority in a next refresh operation, i.e., any of an auto refresh operation and a self refresh operation. For example, although the word line WL9 is originally set to be refreshed in a next refresh operation, a word line (for example, the word line WL6) corresponding to the weak address WEAK_ADD is refreshed prior to the word line WL9. Namely, by refreshing with priority a word line (for example, the word line WL6) of which data is highly probable to be lost, the data may be prevented from being lost. After the word line (for example, the word line WL6) corresponding to the weak address WEAK_ADD is refreshed, a refresh operation is performed in the order originally set (starting from the word line WL9).

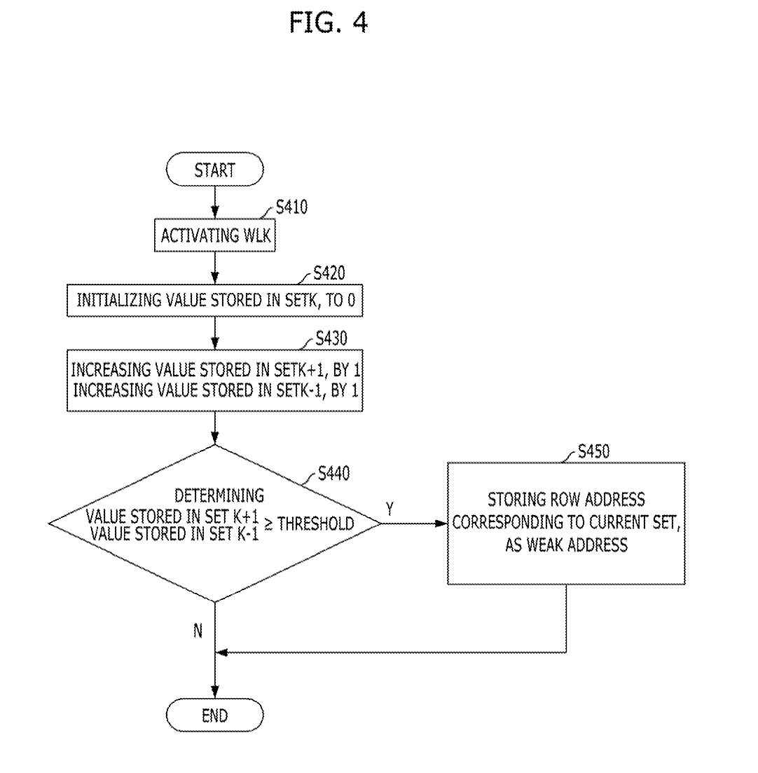

FIG. 4 is a flow chart explaining operations of the memory device described in FIGS. 2 and 3. The operations of the memory device will be described below with reference to FIG. 4.

First, a K^{th} word line WLK (K is an integer equal to or larger than 1 and equal to or smaller than N) corresponding to the row address R_ADD may be activated in the normal cell array 210 (S410). The activation of the K^{th} word line WLK may be implemented in the active operation and the refresh operation.

In response to the activation of the K^{th} word line WLK in the normal cell array 210, the value stored in a K^{th} memory set SETK in the dummy cell array 220 may be initialized to 0 (S420). The reason why the value stored in the K^{th} memory set SETK is initialized to 0 is because the data of the K^{th} word line WLK becomes most stable data by the activation of the K^{th} word line WLK.

The values stored in memory sets SETK+1 and SETK−1 corresponding to adjacent word lines WLK+1 and WLK−1 of the K^{th} word line WLK may be increased by 1 (S430). This is because the data of the adjacent word lines WLK+1 and WLK−1 become unstable by the activation of the K^{th} word line WLK. Although the adjacent word lines of the K^{th} word line WLK are presented as the K+1^{th} word line WLK+1 and the K−1^{th} word line WLK−1, one of these word lines WLK+1 and WLK−1 may not be an adjacent word line. For example, while the word line WL 4 has two adjacent word lines WL3 and WL5, the word line WL1 may have one adjacent word line WL2, and the word line WL15 may have one adjacent word line WL14.

Whether the values of the memory sets SETK+1 and SETK−1 Increased in the step S430 are equal to or larger than the threshold (for example, 60000) is determined (S440). When the values stored in the memory sets SETK+1 and SETK−1 are equal to or larger than the threshold, it may be determined that the data of word lines corresponding to the memory sets SETK+1 and SETK−1 are highly susceptible to be lost.

When it is determined as a result of determination in the step S440 that the values stored in the memory sets SETK+1 and SETK−1 are equal to or larger than the threshold, the row addresses R_ADD designating word lines corresponding to the memory sets SETK+1 and SETK−1 are stored as the weak addresses WEAK_ADD (S450). For example, when the value stored in the memory set SETK+1 is equal to or larger than the threshold, the row address R_ADD designating the word line WLK+1 is stored as the weak address WEAK_ADD, and when the value stored in the memory set SETK−1 is equal to or larger than the threshold, the row address R_ADD designating the word line WLK−1 is stored as the weak address WEAK_ADD. As a word line corresponding to the weak address WEAK_ADD stored in the step S450 is refreshed with priority in a next refresh operation, loss of data is prevented.

By an electronic device according to the above-described embodiments, the data of word lines may be prevented from being lost due to frequent activation of adjacent word lines.

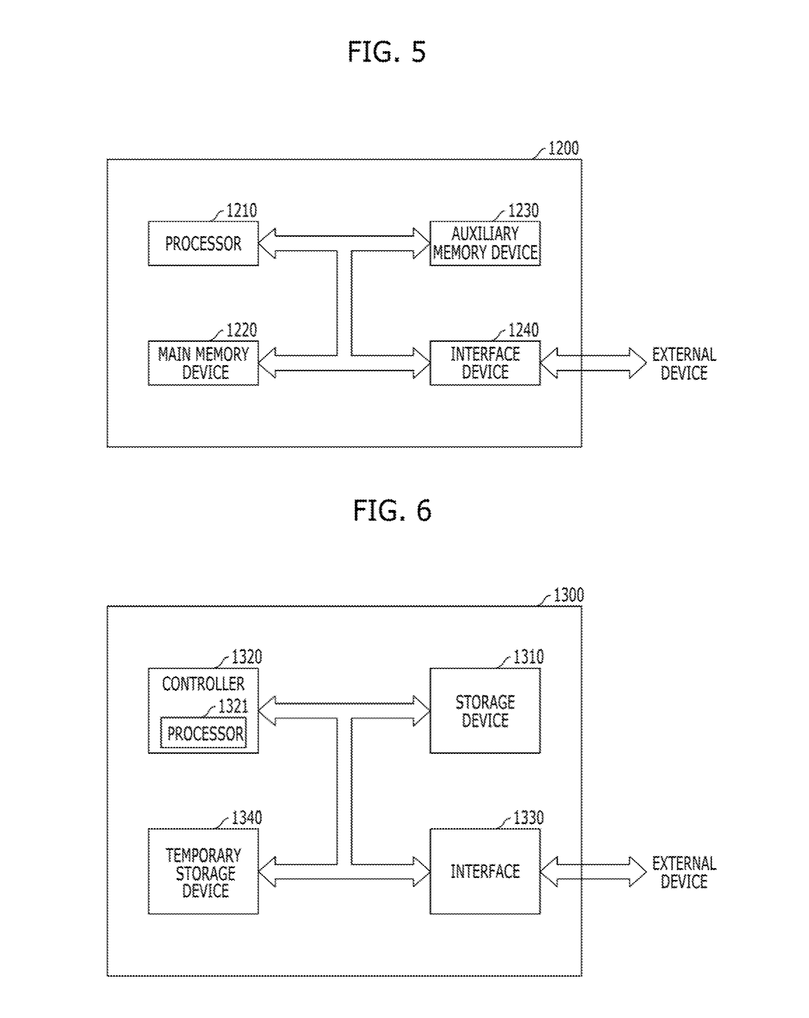

The above and other memory circuits or semiconductor devices based on the disclosed technology may be used in a range of devices or systems. FIGS. 5-7 provide some examples of devices or systems that may implement the memory circuits disclosed herein.

FIG. 5 is a configuration diagram of a system implementing memory circuitry in accordance with an embodiment of the present invention.

Referring to FIG. 5, a system 1200 as an apparatus for processing data may perform operations, such as input, processing, output, communication, storage, etc. to conduct a series of manipulations for data. The system 1200 may include a processor 1210, a main memory device 1220, an auxiliary memory device 1230, an interface device 1240, and so on. The system 1200 of the exemplary embodiment may be various electronic systems, which operate using processors, such as a computer, a server, a PDA (personal digital assistant), a portable computer, a web tablet, a wireless phone, a mobile phone, a smart phone, a digital music player, a PMP (portable multimedia player), a camera, a GPS (global positioning system), a video camera, a voice recorder, a telematics, an audio visual (AV) system, a smart television, and so on.

The processor 1210 decodes inputted commands, and processes and controls operation, comparison, etc. for the data stored in the system 1200. The processor 1210 may include a microprocessor unit (MPU), a central processing unit (CPU), a single/multi-core processor, a graphic processing unit (GPU), an application processor (AP), a digital signal processor (DSP), and so on. The main memory device 1220 is a storage which may temporarily store, call and execute program codes or data from the auxiliary memory device 1230 when programs are executed and may conserve memorized contents even when power supply is cut off. The main memory device 1220 may include one or more of the above-described semiconductor devices in accordance with the embodiments. For example, the main memory device 1220 may include a cell array including first to N^{th} (N is an integer equal to or larger than 2) word lines, first to N^{th} memory sets respectively corresponding to the first to N^{th} word lines, and an activation number updating block configured to, when a K^{th} (K is an integer equal to or larger than 1 and equal to or smaller than N) word line is activated, initialize a value stored in a K^{th} memory set, and increase values stored in memory sets corresponding to adjacent word lines of the K^{th} word line. Since the data of word lines may be prevented from being lost due to frequent activation of adjacent word lines, stability of data may be improved. Through this, the stability of the main memory device 1220 may be improved. Since the main memory device 1220 according to the exemplary embodiment may be improved in stability, the system 1200 may be improved in performance.

Also, the main memory device 1220 may further include a static random access memory (SRAM), a dynamic random access memory (DRAM), and so on, of a volatile memory type in which all contents are erased when power supply is cut off. Alternatively, the main memory device 1220 may not include the semiconductor devices according to the embodiments, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 may store a larger amount of data. The auxiliary memory device 1230 may include one or more of the above-described semiconductor devices in accordance with the embodiments. For example, the auxiliary memory device 1230 may include a cell array including first to N^{th} (N is an integer equal to or larger than 2) word lines, first to N^{th} memory sets respectively corresponding to the first to N^{th} word lines, and an activation number updating block configured to initialize a value stored in a KM memory set and increase values stored in memory sets corresponding to adjacent word lines of the K^{th} word line when a K^{th} (K is an integer equal to or larger than 1 and equal to or smaller than N) word line is activated. Since the data of word lines may be prevented from being lost due to frequent activation of adjacent word lines, stability of data may be improved. Through this, the stability of the auxiliary memory device 1230 may be improved. Since the auxiliary memory device 1230 according to the exemplary embodiment may be improved in stability, the system 1200 may be reduced in size and may be improved in performance.

Also, the auxiliary memory device 1230 may further include a data storage system (see the reference numeral 1300 of FIG. 6) such as a magnetic tape using magnetism, a magnetic disk, a laser disk using optics, a magneto-optical disc using both magnetism and optics, a solid state disk (SSD), a universal serial bus (USB) memory, a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Alternatively, the auxiliary memory device 1230 may not include the semiconductor devices according to the embodiments, but may include data storage systems (see the reference numeral 1300 of FIG. 6) such as a magnetic tape using magnetism, a magnetic disk, a laser disk using optics, a magneto-optical disc using both magnetism and optics, a solid state disk (SSD), a universal serial bus (USB) memory, a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the exemplary embodiment and an external device. The interface device 1240 may be a keypad, a keyboard, a mouse, a speaker, a mike, a display, various human interface devices (HIDs), a communication device and so on. The communication device may include a module capable of being connected with a wired network, a module capable of being connected with a wireless network and both of them.

The wired network module may include a local area network (LAN), a universal serial bus (USB), an Ethernet, power line communication (PLC) and send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB) to send and receive data without transmit lines, and so on.

FIG. 6 is a configuration diagram of a data storage system implementing memory circuitry in accordance with an embodiment of the present invention.

Referring to FIG. 6, a data storage system 1300 may include a storage device 1310, which has a nonvolatile characteristic as a component for storing data, a controller 1320, which controls the storage device 1310, an interface 1330 for connection with an external device, and a temporary storage device 1340 for storing data temporarily. The data storage system 1300 may be a disk type, such as a hard disk drive (HDD), a compact disc read only memory (CDROM), a digital versatile disc (DVD), a solid state disk (SSD), and so on, and a card type, such as a universal serial bus (USB) memory, a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for processing commands inputted through the interface 1330 from an outside of the data storage system 1300 and so on.

The interface 1330 may perform exchange of commands and data between the data storage system 1300 and the external device. In the case where the data storage system 1300 is a card type, the interface 1330 may be compatible with interfaces which are used in devices, such as a universal serial bus (USB) memory, a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices.

If the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), USB (universal serial bus), and so on, or be compatible with the Interfaces, which are similar to the above mentioned interfaces. The interface 1330 may be compatible with two or more interfaces having different types from each other.

The temporary storage device 1340 may store data temporarily for efficiently transferring data between the interface 1330 and the storage device 1310 according to diversifications and high performance of an interface with an external device, a controller and a system. The temporary storage device 1340 for temporarily storing data may include one or more of the above-described semiconductor devices in accordance with the embodiments. The temporary storage device 1340 implementation may include a cell array including first to N^{th} (N is an integer equal to or larger than 2) word lines, first to N^{th} memory sets respectively corresponding to the first to N^{th} word lines, and an activation number updating block configured to initialize a value stored in a K^{th} memory set and increase values stored in memory sets corresponding to adjacent word lines of the Km word line when a K^{th} (K is an integer equal to or larger than 1 and equal to or smaller than N) word line is activated. Since the data of word lines may be prevented from being lost due to frequent activation of adjacent word lines, stability of data may be improved. Through this, the stability of the temporary storage device 1340 may be improved. Since the temporary storage device 1340 according to the exemplary embodiment may be improved in stability, the data storage system 1300 may be improved in performance.

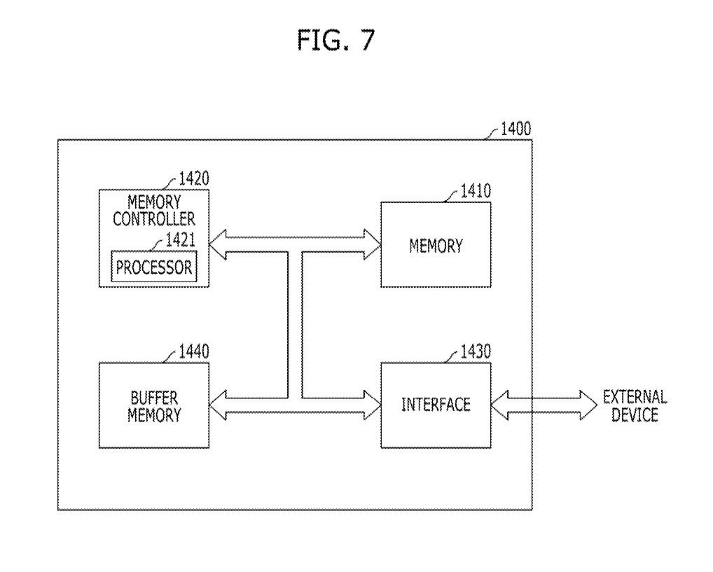

FIG. 7 is a configuration diagram of a memory system in accordance with an embodiment of the present invention.

Referring to FIG. 7, a memory system 1400 may include a memory 1410, which has a nonvolatile characteristic as a component for storing data, a memory controller 1420, which controls the memory 1410, an interface 1430 for connection with an external device, and so on. The memory system 1400 may be a card type such as a solid state disk (SSD), a universal serial bus (USB) memory, a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with the embodiments. For example, the memory 1410 may include a cell array including first to N^{th} (N is an integer equal to or larger than 2) word lines, first to N^{th} memory sets respectively corresponding to the first to N^{th} word lines, and an activation number updating block configured to initialize a value stored in a K^{th} memory set and increase values stored in memory sets corresponding to adjacent word lines of the K^{th} word line when a K^{th} (K is an integer equal to or larger than 1 and equal to or smaller than N) word line is activated. Since the data of word lines may be prevented from being lost due to frequent activation of adjacent word lines, stability of data may be improved. Through this, the stability of the memory 1410 may be improved. Since the memory 1410 according to the exemplary embodiment may be improved in stability, the memory system 1400 may be improved in performance.

Also, the memory 1410 according to the present embodiment may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for processing commands inputted through the interface 1430 from an outside of the memory system 1400.

The interface 1430 may perform exchange of commands and data between the memory system 1400 and the external device. The interface 1430 may be compatible with interfaces which are used in devices, such as a universal serial bus (USB) memory, a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with two or more interfaces having different types from each other.

The memory system 1400 according to the exemplary embodiment may further include a buffer memory 1440 for efficiently transferring data between the interface 1430 and the memory 1410 according to diversification and high performance of an interface with an external device, a memory controller and a memory system. For example, the buffer memory 1440 for temporarily storing data may include one or more of the above-described memory circuits in accordance with the embodiments. The buffer memory 1440 implementation may include a cell array including first to N^{th} (N is an integer equal to or larger than 2) word lines, first to N^{th} memory sets respectively corresponding to the first to N^{th} word lines, and an activation number updating block configured to initialize a value stored in a K^{th} memory set and increase values stored in memory sets corresponding to adjacent word lines of the K^{th} word line when a K^{th} (K is an integer equal to or larger than 1 and equal to or smaller than N) word line is activated. Since the data of word lines may be prevented from being lost due to frequent activation of adjacent word lines, stability of data may be improved. Through this, the stability of the buffer memory 1440 may be improved. Since the buffer memory 1440 according to the exemplary embodiment may be improved in stability, the memory system 1400 may be improved in performance.

Moreover, the buffer memory 1440 according to the exemplary embodiment may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Alternatively, the buffer memory 1440 may not include the semiconductor devices according to the embodiments, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

Features in the above examples of electronic devices or systems in FIGS. 5-7 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

While the present invention has been described with respect to the specific embodiments, it will be apparent to those skilled in the art that various changes and modifications may be made without departing from the spirit and scope of the invention as defined in the following claims.

Also, while a volatile memory which needs a refresh is exemplified in the above-described embodiments of a memory device, it is to be noted that the above-described embodiments may be applied to even to a nonvolatile memory to prevent a phenomenon that the data of word lines are likely to be lost due to excessive accesses to adjacent word lines.

What is claimed is:

1. An electronic device including a semiconductor memory, the semiconductor memory comprising:
a cell array including first to N^{th} word lines, where the N is an integer equal to or larger than 2;
first to N^{th} memory sets respectively corresponding to the first to N^{th} word lines; and
an activation number updating block suitable for, when a K^{th} word line of the word lines is activated, initializing a value stored in a K^{th} memory set and increasing values stored in memory sets corresponding to adjacent word lines of the K^{th} word line, among the memory sets, wherein the K is an integer equal to or larger than 1 and equal to or smaller than N.

2. The electronic device according to claim 1, wherein the semiconductor memory further comprises:
a weak address storage block suitable for storing an address of a word line corresponding to a memory set of which a value reaches a threshold, among the memory sets.

3. The electronic device according to claim 2, wherein a word line corresponding to an address stored in the weak address storage block is refreshed with priority, among the word lines, in a refresh operation of the semiconductor memory.

4. The electronic device according to claim 1, wherein the semiconductor memory further comprises:
an address mapping block suitable for generating addresses which designate the K^{th} memory set and the memory sets corresponding to the adjacent word lines of the K^{th} word line, in response to an address which designates the K^{th} word line.

5. The electronic device according to claim 1, wherein the activation number updating block comprises:
an initialization unit suitable for initializing the value stored in the K^{th} memory set when the K^{th} word line is activated; and
an increasing unit suitable for increasing by 1 the values stored in the memory sets corresponding to the adjacent word lines of the K^{th} word line when the K^{th} word line is activated.

6. The electronic device according to claim 1, wherein the semiconductor memory further comprises:
a threshold determination block suitable for determining whether or not the values stored in the memory sets corresponding to the adjacent word lines of the K^{th} word line reach the threshold.

7. The electronic device according to claim 1, further comprising a processing system which includes:
a processor suitable for decoding a command inputted from an outside of the electronic device and control an operation for information based on a result of decoding the command;
an auxiliary memory device suitable for storing a program for decoding the command and the information;
a main memory device suitable for calling and storing the program and the information from the auxiliary memory device for the processor to perform the operation using the program and the information when executing the program; and
an interface device suitable for performing communication between the processor, the auxiliary memory device or the main memory device, and the outside,
wherein the semiconductor memory unit includes a resistance variable element as a part of the main memory device in the processing system.

8. The electronic device according to claim 1, further comprising a data storage system which includes:
a storage device suitable for storing data and conserving stored data regardless of power supply;
a controller suitable for controlling input and output of data to and from the storage device in response to a command inputted form an outside of the electronic device;
a temporary storage device suitable for temporarily storing data exchanged between the storage device and the outside; and
an interface suitable for performing communication between at least one of the storage device, the controller, and the temporary storage device and the outside,
wherein the semiconductor memory unit includes a resistance variable element as a part of the temporary storage device in the data storage system.

9. The electronic device according to claim 1, further comprising a memory system which includes:
a memory suitable for storing data and conserving stored data regardless of power supply;
a memory controller suitable for controlling input and output of data to and from the memory in response to a command inputted form an outside of the electronic device;
a buffer memory suitable for buffering data exchanged between the memory and the outside; and
an interface suitable for performing communication between at least one of the memory, the memory controller, and the buffer memory and the outside,
wherein the semiconductor memory unit includes a resistance variable element as a part of the buffer memory in the memory system.

10. A method for operating a semiconductor memory, comprising:
activating a K^{th} word line of N^{th} word lines in a normal cell array, wherein the N is an integer equal to or larger than 2, and the K is an integer equal to or larger than 1 and equal to or smaller than N;
initializing a value stored in a K^{th} memory set corresponding to the K^{th} word line in a dummy cell array; and
increasing values stored in memory sets corresponding to adjacent word lines of the K^{th} word line in the dummy cell array.

11. The method according to claim 10, further comprising:
determining whether or not the values stored in the memory sets corresponding to the adjacent word lines reach a threshold; and
storing an address of each of the adjacent word lines as a weak address when the value stored in the memory set corresponding to the adjacent word line is determined to reach the threshold.

12. The method according to claim 11, further comprising:
refreshing a word line corresponding to the weak address with priority in a refresh operation of the semiconductor memory.
